(19) United States
(12) Patent Application Publication
(10) Pub. No.: US 2025/0276667 A1
(43) Pub. Date: Sep. 4, 2025

(54) ANTI-THEFT BRACKET AND VEHICLE CONTROL DEVICE INCLUDING THE SAME

(71) Applicant: HYUNDAI MOBIS CO., LTD., Seoul (KR)

(72) Inventor: Dong Hyun KIM, Yongin-si (KR)

(73) Assignee: HYUNDAI MOBIS CO., LTD., Seoul (KR)

(21) Appl. No.: 18/923,011

(22) Filed: Oct. 22, 2024

(30) Foreign Application Priority Data
Feb. 29, 2024 (KR) 10-2024-0030298

(51) Int. Cl. B60R 25/00; B60R 16/02; B60R 16/023; H01R 13/627

(52) U.S. Cl. CPC B60R 25/002; B60R 16/0215; B60R 16/0231; H01R 13/6272

(57) ABSTRACT

An anti-theft bracket and a vehicle control device therefor are provided. The anti-theft bracket for the vehicle control device includes a connector withdrawal prevention portion configured to block an insertion connector fitted with a housing of the vehicle control device from being withdrawn from the housing, and a housing coupling portion connected to the connector withdrawal prevention portion and fitted with the housing. The housing coupling portion prevents the housing coupling portion and the connector withdrawal prevention portion from being withdrawn from the housing.

### CROSS-REFERENCE TO RELATED APPLICATION(S)

This application claims priority from and the benefit under 35 USC § 119 of Korean Patent Application No. 10-2024-0030298, filed on Feb. 29, 2024, in the Korean Intellectual Property Office, the entire disclosure of which is incorporated by reference for all purposes.

### BACKGROUND

### 1. Field

Exemplary embodiments of the present disclosure relate to an anti-theft bracket, and more particularly, to an anti-theft bracket coupled to a vehicle control device, and the vehicle control device including the same.

### 2. Description of the Related Art

Canada and some European countries, for example, have regulations in place to suppress criminal activity that involves removing connectors from vehicle control devices, such as body control modules (BCMs) and integrated body units (IBUs), and connecting cables to hack or steal vehicles. Therefore, there is a need for an anti-theft bracket that meets the requirement of the regulation.

A background technology related to the present disclosure is disclosed in Korean Patent Application Laid-Open No. 10-2019-0056384 (published on May 24, 2019 and entitled ‘Vehicle Anti-Theft Device’).

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In a general aspect of the disclosure, an anti-theft bracket for a vehicle control device, includes: a connector withdrawal prevention portion configured to block an insertion connector fitted with a housing of the vehicle control device from being withdrawn from the housing; and a housing coupling portion connected to the connector withdrawal prevention portion and fitted with the housing, wherein the housing coupling portion is configured to prevent the housing coupling portion and the connector withdrawal prevention portion from being withdrawn from the housing.

The vehicle control device may include at least one of a body control module (BCM), an integrated body unit (IBU), an engine control module (ECM), or any combination thereof.

The housing of the vehicle control device may include a circuit board installed therein, and the insertion connector may be electrically coupled to the circuit board.

In another general aspect of the disclosure, a vehicle control device includes: a housing including: a connector fitting part; and a bracket fitting part provided at one side of the connector fitting part; an insertion connector fitted with the connector fitting part; and an anti-theft bracket including: a connector withdrawal prevention portion configured to block the insertion connector fitted with the housing from being withdrawn from the connector fitting part; and a housing coupling portion connected to the connector withdrawal prevention portion and fitted with the bracket fitting part, wherein the housing coupling portion is configured to prevent the housing coupling portion from being withdrawn from the bracket fitting part.

The housing coupling portion may include a bracket hook protruding in a direction intersecting a direction in which the anti-theft bracket is inserted into the bracket fitting part.

The housing may include a bracket hook stopper configured to block the bracket hook so that the housing coupling portion inserted into the bracket fitting part does not move in a direction opposite to a direction in which the housing coupling portion is inserted into the bracket fitting part.

The housing may include a housing hook protruding in a direction intersecting a direction in which the anti-theft bracket is inserted into the bracket fitting part.

The housing coupling portion may include a housing hook stopper blocked by the housing hook so that the housing coupling portion inserted into the bracket fitting part does not move in a direction opposite to a direction in which the housing coupling portion is inserted into the bracket fitting part.

The connector withdrawal prevention portion may cover an inlet of the bracket fitting part.

The anti-theft bracket may further include a connector insertion portion connected to the connector withdrawal prevention portion and inserted into the insertion connector.

The insertion connector may include: a groove portion into which the connector insertion portion is inserted; and a bracket stopper part positioned between the housing coupling portion and the connector insertion portion and facing the connector withdrawal prevention portion when the housing coupling portion is fitted with the bracket fitting part.

The anti-theft bracket may further include a blade portion being in surface contact with an inner surface that defines an inlet of the bracket fitting part.

The blade portion may be bent and extend from the housing coupling portion, and the connector withdrawal prevention portion may block the blade portion so that the blade portion is not folded in a direction in which an angle between the blade portion and the housing coupling portion decreases.

The anti-theft bracket may be manufactured by performing a press processing on a metal board.

The vehicle control device may include at least one of a body control module (BCM), an integrated body unit (IBU), an engine control module (ECM), or any combination thereof.

The housing of the vehicle control device may include a circuit board installed therein, and the insertion connector may be electrically coupled to the circuit board.

### BRIEF DESCRIPTION OF THE DRAWINGS

FIG. 1 is a perspective view of a vehicle control device according to an embodiment of the present disclosure.

FIG. 2 is an enlarged perspective view of part II in FIG. 1, i.e., a view illustrating a state in which an insertion connector and an anti-theft bracket are spaced apart from a housing.

FIG. 3 is a cross-sectional view taken along line III-III in FIG. 1.

FIG. 4 is a cross-sectional view taken along line IV-IV in FIG. 1.

FIG. 5 is a partially enlarged front view illustrating a part of the housing having a connector fitting part and a bracket fitting part in FIG. 2.

FIG. 6 is a partially enlarged perspective view illustrating a cover illustrated in FIG. 5 when viewed from below.

FIG. 7 is a partially cut-away perspective view of the cover in FIG. 5 taken along line VII-VII when viewed from below.

FIG. 8 is a perspective view illustrating a state in which the insertion connector and the anti-theft bracket in FIG. 2 are separated when viewed from above.

FIG. 9 is a perspective view illustrating a state in which the insertion connector and the anti-theft bracket in FIG. 2 are separated when viewed from below.

### DETAILED DESCRIPTION

Hereinafter, an anti-theft bracket and a vehicle control device including the same will be described in detail with reference to the accompanying drawings through various exemplary embodiments. The terminologies used in the present specification are used to appropriately express an exemplary embodiment of the present disclosure and may vary depending on the intention of a user or operator or on usual practice in the art to which the present disclosure pertains. Therefore, the definition of the terms should be made on the basis of the entire contents of the present specification.

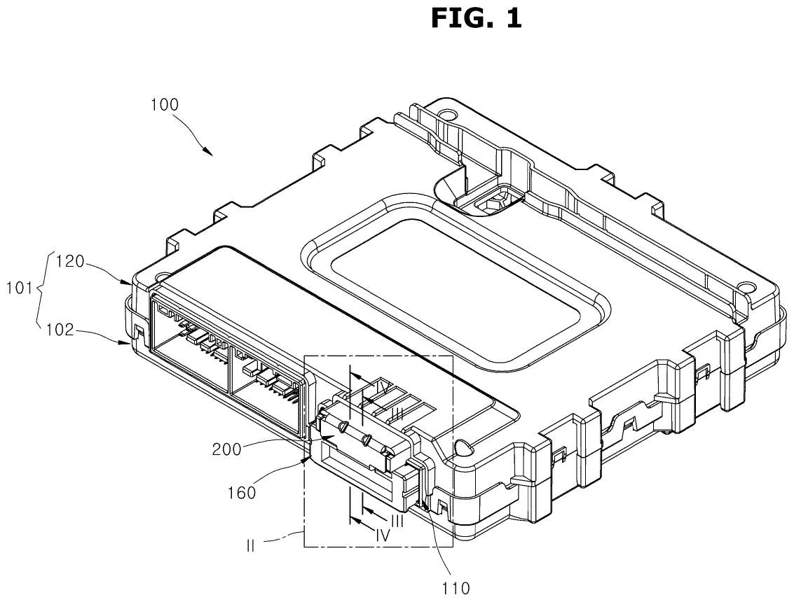

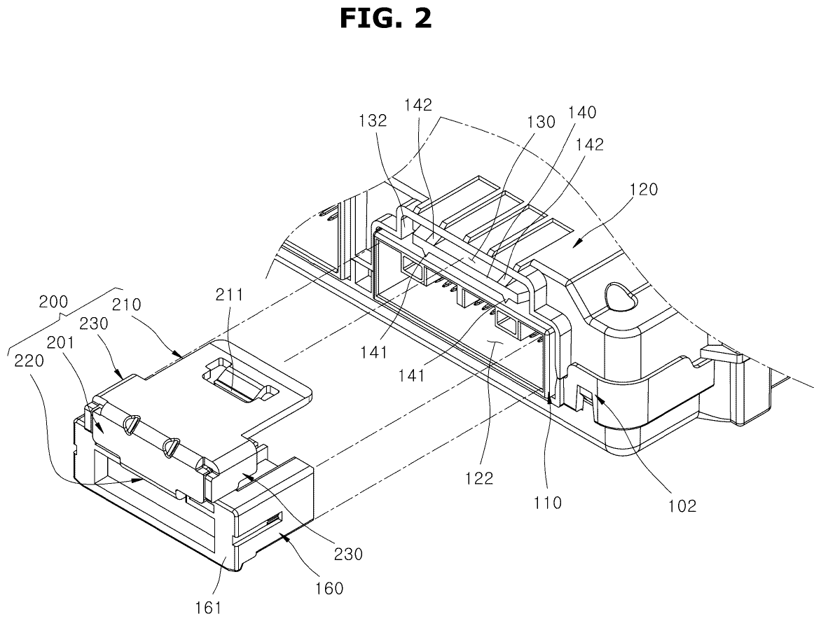

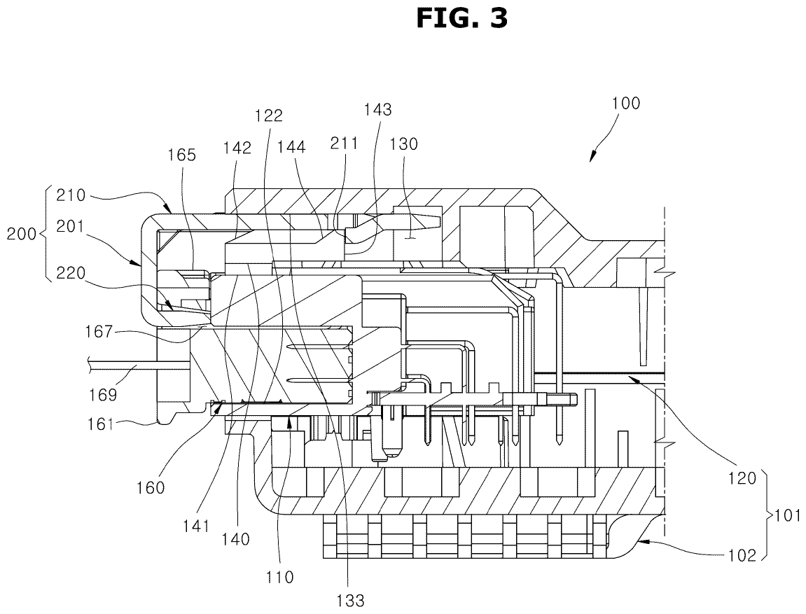

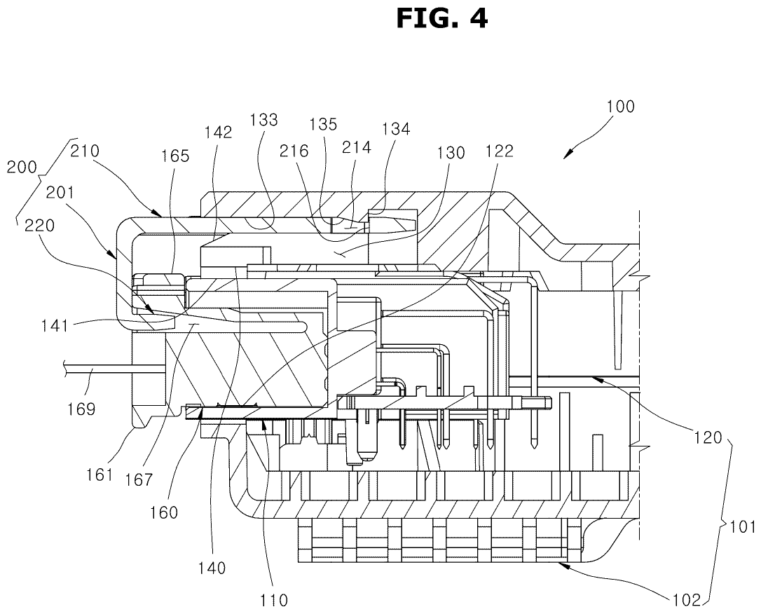

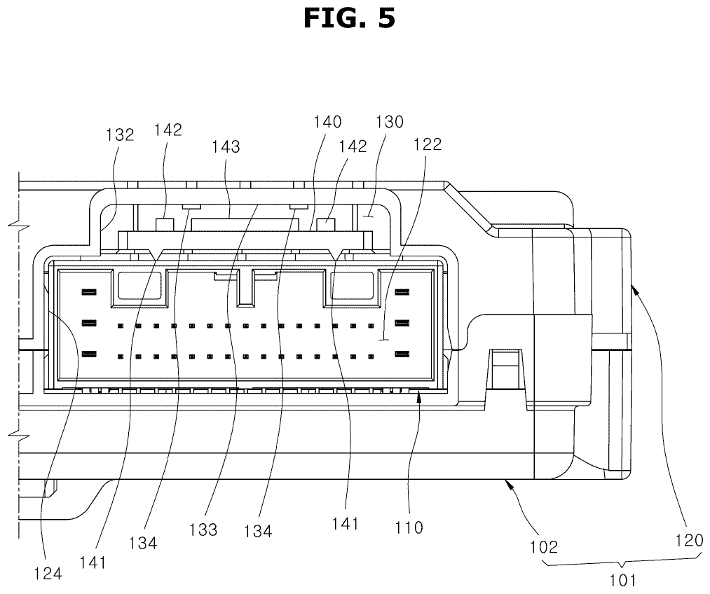

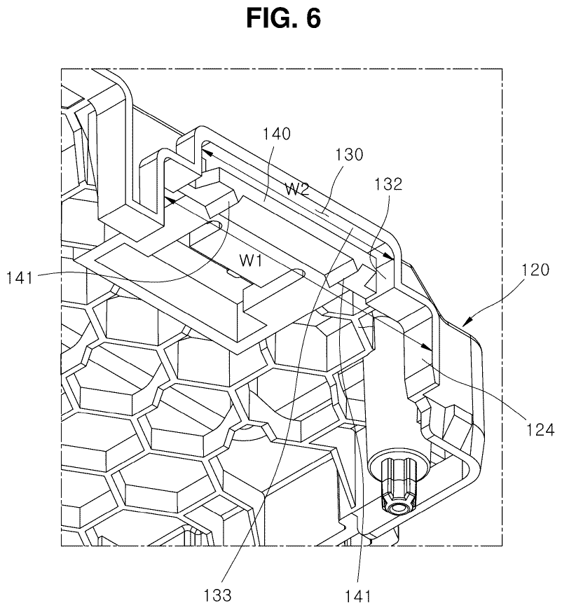

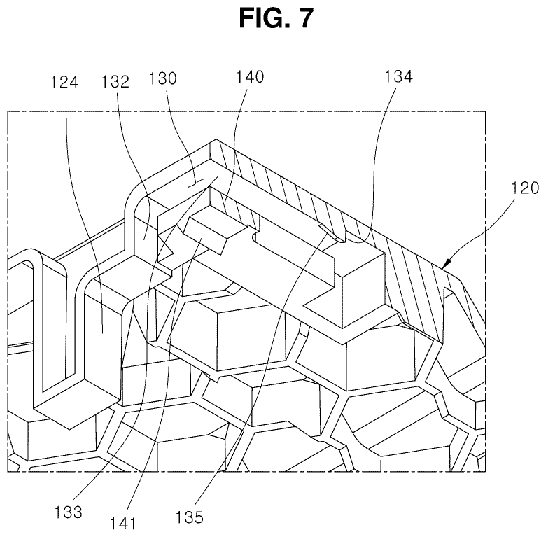

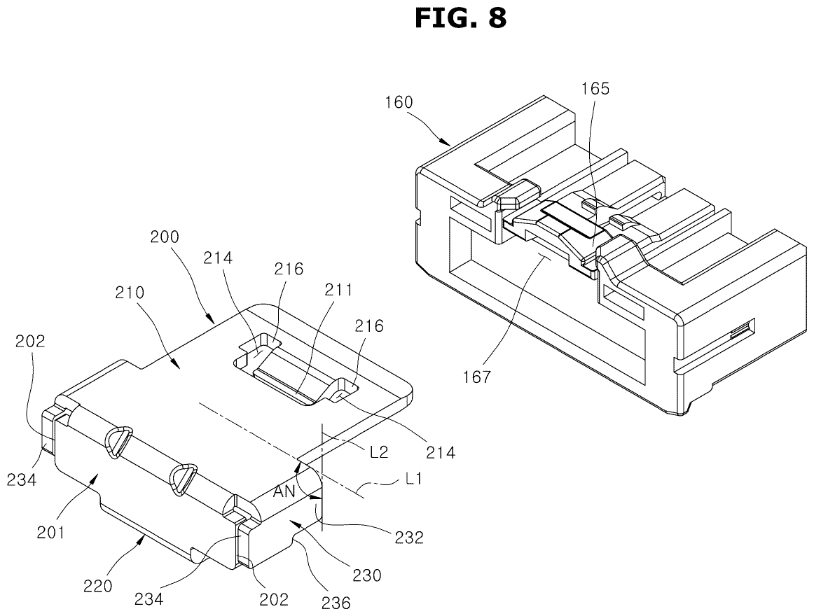

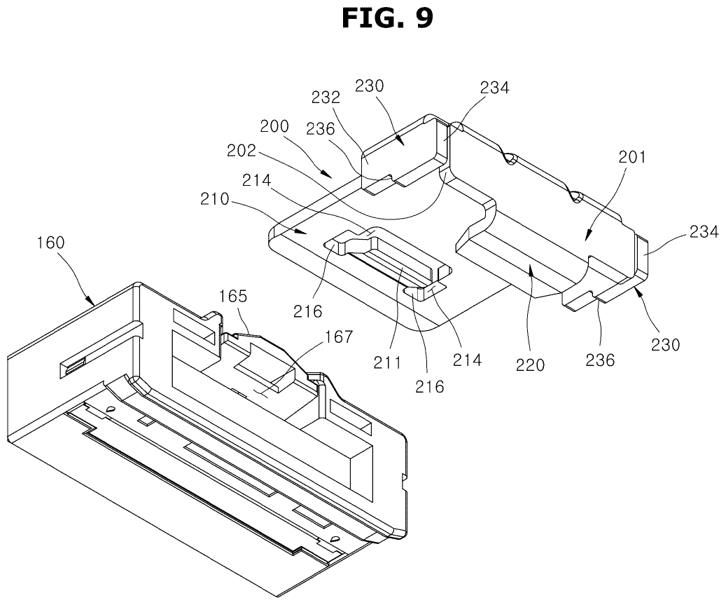

FIG. 1 is a perspective view of a vehicle control device according to an embodiment of the present disclosure, FIG. 2 is an enlarged perspective view of part II in FIG. 1, i.e., a view illustrating a state in which an insertion connector and an anti-theft bracket are spaced apart from a housing, FIG. 3 is a cross-sectional view taken along line III-III in FIG. 1, FIG. 4 is a cross-sectional view taken along line IV-IV in FIG. 1, FIG. 5 is a partially enlarged front view illustrating a part of the housing having a connector fitting part and a bracket fitting part in FIG. 2, FIG. 6 is a partially enlarged perspective view illustrating a cover illustrated in FIG. 5 when viewed from below, FIG. 7 is a partially cut-away perspective view of the cover in FIG. 5 taken along line VII-VII when viewed from below, FIG. 8 is a perspective view illustrating a state in which the insertion connector and the anti-theft bracket in FIG. 2 are separated when viewed from above, and FIG. 9 is a perspective view illustrating a state in which the insertion connector and the anti-theft bracket in FIG. 2 are separated when viewed from below.

With reference to FIGS. 1 to 9, a vehicle control device 100 according to the embodiment of the present disclosure refers to a device configured to communicate with and control devices such as headlamps, power seats, an air conditioning device, a smart key, a driving assistance device, and a parking assistance device of a vehicle. For example, a body control module (BCM) or an integrated body unit (IBU) may be the vehicle control device 100. In another embodiment of the present disclosure, the vehicle control device 100 may include a body control module (BCM), an integrated body unit (IBU), an engine control module (ECM), or any combination thereof.

The vehicle control device 100 may include a housing 101, an insertion connector 160, and an anti-theft bracket 200. The housing 101 may include a base 102, a cover 120, and a fixing connector 110. The cover 120 may be coupled to the base 102. A circuit pattern may be formed in an internal space of the housing 101 defined by the base 102 and the cover 120, and a circuit board on which electronic elements are mounted may be installed in the internal space of the housing 101.

The fixing connector 110 may be installed at one side the base 102 and the cover 120 coupled to each other. A through-hole is formed at one side of the base 102 and the cover 120 and has a first inner interval W1 and a second inner interval W2 smaller than the first inner interval W1. In this case, among the inner surfaces that define a shape of the through-hole, an interval between a pair of first inner surfaces 124 facing each other is referred to as the first inner interval W1, and an interval between a pair of second inner surfaces 132 facing each other and stepped from the pair of first inner surfaces 124 is referred to as the second inner interval W2.

An outer surface of the fixing connector 110 is in surface contact with the pair of first inner surfaces 124. The fixing connector 110 may be electrically coupled to the circuit board installed in the internal space of the housing 101. More specifically, the fixing connector 110 may be electrically coupled to the circuit board fixedly supported on the base 102, and the outer surface of the fixing connector 110 is in surface contact with and supported on the pair of first inner surfaces 124, such that the fixing connector 110 may be fixedly supported on the base 102 and the cover 120.

The housing 101 includes a connector fitting part 122 and a bracket fitting part 130. The connector fitting part 122 may include a concave groove formed in the fixing connector 110 and formed to be visible from the outside of the housing 101. The bracket fitting part 130 is provided at one side of the connector fitting part 122. For example, the bracket fitting part 130 may be provided above the connector fitting part 122.

The insertion connector 160 is fitted with the connector fitting part 122. More specifically, the insertion connector 160 may be fitted with the concave groove of the fixing connector 110. The insertion connector 160 may include a connector body 161 and a connector cable 169. The connector body 161 may be fitted with and fixed to the connector fitting part 122 to close the connector fitting part 122.

When the connector body 161 is fitted with the connector fitting part 122, a conductor of the fixing connector 110 and a conductor of the insertion connector 160 may be electrically connected. The connector cable 169 may be electrically connected to the conductor of the insertion connector 160 so that a device or sensor included in the vehicle and the circuit board installed in the housing 101 are connected in a communicable manner.

The anti-theft bracket 200 includes a connector withdrawal prevention portion 201 and a housing coupling portion 210. The connector withdrawal prevention portion 201 blocks the insertion connector 160 to prevent the insertion connector 160 from being withdrawn from the connector fitting part 122. The housing coupling portion 210 is connected to the connector withdrawal prevention portion 201 and fitted with the bracket fitting part 130 so as not to be withdrawn from the bracket fitting part 130.

When the housing coupling portion 210 is fitted with the bracket fitting part 130 and fixed to the housing 101 so as not to be separated from the housing 101, the connector withdrawal prevention portion 201 may cover an inlet of the bracket fitting part 130 so that the inlet of the bracket fitting part 130 is not exposed.

The cover 120 includes a bracket coupling plate 140 provided in the inlet of the bracket fitting part 130. The bracket coupling plate 140 is a plate-shaped part extending in a leftward/rightward direction. Two opposite ends of the bracket coupling plate 140 are supported on the pair of second inner surfaces 132 facing each other. The housing coupling portion 210 enters between inner surfaces 133 of the cover 120 that face an upper surface of the bracket coupling plate 140 and an upper surface of the bracket coupling plate 140, such that the housing coupling portion 210 is fitted with the bracket fitting part 130.

The housing coupling portion 210 may include a bracket hook 211 protruding in a direction intersecting a direction in which the anti-theft bracket 200 is inserted into the bracket fitting part 130. The bracket hook 211 may protrude to be inclined so as not to prevent the housing coupling portion 210 from entering the bracket fitting part 130.

The housing 101 may include a bracket hook stopper 143 configured to block the bracket hook 211 so that the housing coupling portion 210 inserted into the bracket fitting part 130 does not move in a direction opposite to the direction in which the housing coupling portion 210 is inserted into the bracket fitting part 130. The bracket hook stopper 143 may be provided at an end of the bracket coupling plate 140 in an inward direction of the housing 101.

The bracket coupling plate 140 may further include an inclined surface 144 facing away from the bracket hook stopper 143. When the housing coupling portion 210 is inserted into the housing 101 through the inlet of the bracket fitting part 130, the inclined portion of the bracket hook 211 comes into contact with the inclined surface 144 of the bracket coupling plate 140, and an inclination angle of the bracket hook 211 decreases, such that the bracket hook 211 may climb over the bracket hook stopper 143.

An inclination angle of the bracket hook 211, which has climbed over the bracket hook stopper 143, is elastically restored to an original angle, such that the bracket hook 211 is blocked by the bracket hook stopper 143. Therefore, the housing coupling portion 210 and the anti-theft bracket 200 including the same are not withdrawn from the bracket fitting part 130 as long as the housing coupling portion 210 and the anti-theft bracket 200 are damaged.

The housing 101 may include a housing hook 134 protruding in a direction intersecting the direction in which the anti-theft bracket 200 is inserted into the bracket fitting part 130. For example, the housing hook 134 may protrude from the inner surface 133 of the cover 120 that faces the upper surface of the bracket coupling plate 140. In the embodiment of the present disclosure illustrated in FIGS. 2, 5, 8, and 9, the pair of housing hooks 134 is provided. However, another embodiment of the present disclosure may include three or more housing hooks or a single housing hook.

The housing coupling portion 210 may include a housing hook stopper 216 blocked by the housing hook so that the housing coupling portion 210 inserted into the bracket fitting part 130 does not move in the direction opposite to the direction in which the housing coupling portion 210 is inserted into the bracket fitting part 130. For example, the housing hook stopper 216 may be provided as a pair of housing hook stoppers 216 provided at left and right sides of the bracket hook 211. More specifically, a pair of housing hook accommodation portions 214, which is recessed to accommodate the housing hooks 134, may be formed at left and right sides of the bracket hook 211, and the pair of housing hook stoppers 216 may be provided on the inner surface that defines the pair of housing hook accommodation portions 214.

The housing hook 134 may include an inclined surface 135 inclined so that a distal end of the housing coupling portion 210 may climb over the housing hook 134 without being caught when the housing coupling portion 210 is inserted into the housing 101 through the inlet of the bracket fitting part 130.

The bracket coupling plate 140 may further include inclined guides 142, and protruding ribs 141. The inclined guide 142 guides the housing coupling portion 130 so that the housing coupling portion becomes close to the inner surface 133 of the cover 120, which faces the upper surface of the bracket coupling plate 140, when the housing coupling portion 130 enters the bracket fitting part 130 through the inlet of the bracket fitting part 130. The inclined guide 142 may be provided as a plurality of inclined guides 142 provided to avoid the bracket hook stopper 143.

The protruding rib 141 may protrude downward so as to be in contact with the upper surface of the fixing connector 110. The protruding rib 141 may be provided as a plurality of protruding ribs 141 spaced apart from one another. Because the bracket coupling plate 140 is supported on the fixing connector 110 by means of the protruding ribs 141, the bracket coupling plate 140 may more securely support the housing coupling portion 210 and the anti-theft bracket 200 including the same without sagging downward.

The anti-theft bracket 200 may further include a connector insertion portion 220 and a blade portion 230. The connector insertion portion 220 is connected to the connector withdrawal prevention portion 201 and inserted into the insertion connector 160. The connector insertion portion 220 may be disposed below and spaced apart from the housing coupling portion 210. The housing coupling portion 210 and the connector insertion portion 220 may extend in parallel with the direction in which the housing coupling portion 210 is inserted into the bracket fitting part 130.

The insertion connector 160 includes a groove portion 167 and a bracket stopper part 165. The connector insertion portion 220 may be inserted into the groove portion 167 when the housing coupling portion 210 is inserted into the bracket fitting part 130. When the housing coupling portion 210 is fitted with the bracket fitting part 130, the bracket stopper part 165 may be positioned between the housing coupling portion 210 and the connector insertion portion 220 and face the connector withdrawal prevention portion 201.

The blade portion 230 is in surface contact with the second inner surface 132 that defines the inlet of the bracket fitting part 130. For example, the blade portion 230 may be provided as a pair of blade portions 230 disposed one by one at left and right sides in the width direction of the connector withdrawal prevention portion 201. The blade portion 230 may be bent and extend downward from the housing coupling portion 210.

When the housing coupling portion 210 is fitted with the bracket fitting part 130, an outer surface 232 of one side end of the blade portion 230 is in surface contact with the second inner surface 132 in the longitudinal direction of the housing coupling portion 210.

Therefore, in the state in which the insertion connector 160 is inserted and coupled into the connector fitting part 122 and the housing coupling portion 230 is inserted and coupled into the bracket fitting part 130, no gap, through which a tool, such as a screwdriver or a lever, may be inserted is provided between the inlet of the bracket fitting part 130 and the anti-theft bracket 200. Therefore, the anti-theft bracket 200 and the insertion connector 160 cannot be forcibly separated from the housing 10 within a short time. Therefore, the reliability of the function of preventing vehicle theft is improved.

The blade portion 230 may further include a stepped surface 236 that comes into contact with an edge of the fixing connector 110 when the housing coupling portion 210 is inserted into the bracket fitting part 130. Therefore, in the state in which the insertion connector 160 is inserted and coupled into the connector fitting part 122 and the housing coupling portion 230 is inserted and coupled into the bracket fitting part 130, no gap, into which a tool is inserted, is provided between the inlet of the bracket fitting part 130 and the inlet of the connector fitting part 122, which further improves the reliability of the function of preventing vehicle theft.

The connector withdrawal prevention portion 201 supports the blade portion 230 so that the blade portion 230 is not folded in a direction in which an angle between the blade portion 230 and the housing coupling portion 210 decreases. For example, in FIG. 8, an angle AN, which is defined as an imaginary straight line L1, which extends in the width direction perpendicular to the longitudinal direction of the housing coupling portion 210, and an imaginary straight line L2, which extends in the direction in which the blade portion 230 is bent, intersect each other, may be an angle between the blade portion 230 and the housing coupling portion 210.

An end 234, which is opposite to one side end of the blade portion 230 based on the longitudinal direction of the housing coupling portion 210, overlaps two opposite ends 202 of the connector withdrawal prevention portion 201 based on the width direction of the connector withdrawal prevention portion 201.

Therefore, because the two opposite ends 202 of the connector withdrawal prevention portion 201 block and support the blade portion 230 even though an external force is applied in a direction in which the blade portion 230 is folded with respect to the housing coupling portion 210, the angle AN between the blade portion 230 and the housing coupling portion 210 does not decrease. As a result, the gap between the second inner surface 132 and the blade portion 230 is not enlarged even when an external force is applied by a criminal, which more reliably prevents vehicle theft.

For example, the anti-theft bracket 200 may be manufactured by performing press processing on a metal board such as stainless steel. However, alternatively, the anti-theft bracket 200 of the present disclosure may be manufactured by injection molding a synthetic resin-based material such as engineering plastic or fiber reinforced plastic. Alternatively, the anti-theft bracket 200 may be formed by casting using a metallic material.

The present disclosure described above does not require an additional configuration other than the anti-theft bracket 200 to prevent the detachment of the insertion connector 160. Therefore, the costs required to provide the anti-theft structure of the vehicle may be reduced, and the weight of the vehicle control device 100 may be reduced.

According to the present disclosure, the anti-theft bracket 200 may be easily coupled to the housing 10 so as not to be separated only by being fitted with the housing 101 without using a fastener such as a bolt. Therefore, it is possible to improve the convenience and productivity of the assembling process.

While the present disclosure has been described with reference to the exemplary embodiment depicted in the drawings, the exemplary embodiment is described just for illustration, and those skilled in the art to the present technology pertains will understand that various modifications of the exemplary embodiment and any other exemplary embodiment equivalent thereto are available. Accordingly, the true protection scope of the present disclosure should be determined by the appended claims.

Although exemplary embodiments of the disclosure have been disclosed for illustrative purposes, those skilled in the art will appreciate that various modifications, additions and substitutions are possible, without departing from the scope and spirit of the disclosure as defined in the accompanying claims. Thus, the true technical scope of the disclosure should be defined by the following claims.

What is claimed is:

1. An anti-theft bracket for a vehicle control device, comprising:
a connector withdrawal prevention portion configured to block an insertion connector fitted with a housing of the vehicle control device from being withdrawn from the housing; and
a housing coupling portion connected to the connector withdrawal prevention portion and fitted with the housing,
wherein the housing coupling portion is configured to prevent the housing coupling portion and the connector withdrawal prevention portion from being withdrawn from the housing.

2. The anti-theft bracket of claim 1, wherein the vehicle control device comprises at least one of a body control module (BCM), an integrated body unit (IBU), an engine control module (ECM), or any combination thereof.

3. The anti-theft bracket of claim 1,
wherein the housing of the vehicle control device includes a circuit board installed therein, and
wherein the insertion connector is electrically coupled to the circuit board.

4. A vehicle control device comprising:
a housing comprising:
a connector fitting part; and
a bracket fitting part provided at one side of the connector fitting part;
an insertion connector fitted with the connector fitting part; and
an anti-theft bracket comprising:
a connector withdrawal prevention portion configured to block the insertion connector fitted with the housing from being withdrawn from the connector fitting part; and
a housing coupling portion connected to the connector withdrawal prevention portion and fitted with the bracket fitting part,
wherein the housing coupling portion is configured to prevent the housing coupling portion from being withdrawn from the bracket fitting part.

5. The vehicle control device of claim 4, wherein the housing coupling portion comprises a bracket hook protruding in a direction intersecting a direction in which the anti-theft bracket is inserted into the bracket fitting part.

6. The vehicle control device of claim 5, wherein the housing comprises a bracket hook stopper configured to block the bracket hook so that the housing coupling portion inserted into the bracket fitting part does not move in a direction opposite to a direction in which the housing coupling portion is inserted into the bracket fitting part.

7. The vehicle control device of claim 4, wherein the housing comprises a housing hook protruding in a direction intersecting a direction in which the anti-theft bracket is inserted into the bracket fitting part.

8. The vehicle control device of claim 7, wherein the housing coupling portion comprises a housing hook stopper blocked by the housing hook so that the housing coupling portion inserted into the bracket fitting part does not move in a direction opposite to a direction in which the housing coupling portion is inserted into the bracket fitting part.

9. The vehicle control device of claim 4, wherein the connector withdrawal prevention portion covers an inlet of the bracket fitting part.

10. The vehicle control device of claim 4, wherein the anti-theft bracket further comprises a connector insertion portion connected to the connector withdrawal prevention portion and inserted into the insertion connector.

11. The vehicle control device of claim 10, wherein the insertion connector comprises:
a groove portion into which the connector insertion portion is inserted; and
a bracket stopper part positioned between the housing coupling portion and the connector insertion portion and facing the connector withdrawal prevention portion when the housing coupling portion is fitted with the bracket fitting part.

12. The vehicle control device of claim 4, wherein the anti-theft bracket further comprises a blade portion being in surface contact with an inner surface that defines an inlet of the bracket fitting part.

13. The vehicle control device of claim 12,
wherein the blade portion is bent and extends from the housing coupling portion, and
wherein the connector withdrawal prevention portion blocks the blade portion so that the blade portion is not folded in a direction in which an angle between the blade portion and the housing coupling portion decreases.

14. The vehicle control device of claim 4, wherein the anti-theft bracket is manufactured by performing a press processing on a metal board.

15. The vehicle control device of claim 4, wherein the vehicle control device comprises at least one of a body control module (BCM), an integrated body unit (IBU), an engine control module (ECM), or any combination thereof.

16. The anti-theft bracket of claim 4,
wherein the housing of the vehicle control device includes a circuit board installed therein, and
wherein the insertion connector is electrically coupled to the circuit board.
